(19) United States
(12) Patent Application Publication
(10) Pub. No.: US 2018/0364503 A1
(43) Pub. Date: Dec. 20, 2018

(54) TFT ARRAY SUBSTRATE AND LIQUID CRYSTAL DISPLAY PANEL

(71) Applicant: Wuhan China Star Optoelectronics Technology Co., Ltd., Wuhan, Hubei (CN)

(72) Inventors: Cheng CHEN, Shenzhen, Guangdong (CN); Liang MA, Shenzhen, Guangdong (CN)

(73) Assignee: Wuhan China Star Optoelectronics Technology Co., Ltd., Wuhan, Hubei (CN)

(21) Appl. No.: 15/535,656

(22) PCT Filed: Apr. 7, 2017
(86) PCT No.: PCT/CN2017/079702

§ 371 Date: Jun. 13, 2017

(30) Foreign Application Priority Data
Mar. 8, 2017 (CN) 201710136806.7

(51) Int. Cl. G02F 1/136; H01L 27/12; H01L 29/06; H01L 29/786; H01L 29/66

(52) U.S. Cl. CPC G02F 1/136; H01L 27/12; H01L 29/66757; H01L 29/78675; H01L 29/06

(57) ABSTRACT

The present invention provides a TFT array substrate, comprising a substrate and a TFT switch formed on the substrate, and the TFT switch comprises a polysilicon layer, a gate, a first lightly doped region and a heavily doped region, and the polysilicon layer comprises two opposite extending sections and a main section connecting ends of the two extending sections, and the gate is disposed across the two extending sections, and the heavy doped region is formed in the main section of the polysilicon layer and at one side of the gate, and the first lightly doped region is formed at the middle of the heavily doped region.

### CROSS REFERENCE

This application claims the priority of Chinese Patent Application No. 2017101368067, entitled “TFT array substrate and liquid crystal display panel”, filed on Mar. 8, 2017, the disclosure of which is incorporated herein by reference in its entirety.

### FIELD OF THE INVENTION

The present invention relates to a touch panel technology field, and more particularly to a TFT array substrate and a liquid crystal display panel.

### BACKGROUND OF THE INVENTION

When the Thin Film Transistor (TFT) of the liquid crystal display panel is turned off, there is a leakage phenomenon in the doped region to cause the a change in the voltage difference between the pixel electrode and the common electrode. The serious leakage will lead to pixel gray scale changes, resulting in string and other adverse reactions, so that the optical quality of the LCD screen drops. At present mainly the following two aspects are considered for improvement, 1. Increasing the pixel storage capacitor; 2. Reducing the leakage current of the thin film transistor. One way to reduce the leakage current of the thin film transistor is to increase the channel region length or to increase the channel number of the TFT, but this will reduce the pixel aperture ratio.

### SUMMARY OF THE INVENTION

The present invention provides a TFT array substrate, which does not influence the pixel aperture ratio to reduce the thin film transistor switch leakage current.

The present application further provides a liquid crystal display panel.

The TFT array substrate of the present application comprises a substrate and a TFT switch formed on the substrate, wherein the TFT switch comprises a polysilicon layer, a gate, a first lightly doped region and a heavily doped region, and the polysilicon layer comprises two opposite extending sections and a main section connecting ends of the two extending sections, and the gate is disposed across the two extending sections, and the heavy doped region is formed in the main section of the polysilicon layer and at one side of the gate, and the first lightly doped region is formed at the middle of the heavily doped region.

An auxiliary heavily doped region is further disposed on the polysilicon layer at the other side of the gate.

The first lightly doped region is formed by implementing second doping to the heavily doped region.

The TFT switch comprises second lightly doped regions, and the second lightly doped regions are at two sides of the gate between the heavily doped region and the auxiliary heavily doped region.

The first lightly doped region is formed in the same process step as the second lightly doped region.

The present application provides a liquid crystal display panel, comprising a color film substrate, a TFT array substrate and a liquid crystal layer between the color film substrate and the TFT array substrate, and the TFT array substrate comprises a substrate and a TFT switch formed on the substrate, wherein the TFT switch comprises a polysilicon layer, a gate, a first lightly doped region and a heavily doped region, and the polysilicon layer comprises two opposite extending sections and a main section connecting ends of the two extending sections, and the gate is disposed across the two extending sections, and the heavy doped region is formed in the main section of the polysilicon layer and at one side of the gate, and the first lightly doped region is formed at the middle of the heavily doped region.

An auxiliary heavily doped region is further disposed on the polysilicon layer at the other side of the gate.

The first lightly doped region is formed by implementing second doping to the heavily doped region.

The TFT switch comprises second lightly doped regions, and the second lightly doped regions are at two sides of the gate between the heavily doped region and the auxiliary heavily doped region.

The first lightly doped region is formed in the same process step as the second lightly doped region.

The TFT switch described in the present application provides a lightly doped region in the heavily doped region without affecting the aperture ratio of the array substrate and the manufacturing process, thereby effectively reducing the leakage current of the TFT switch without affecting the aperture ratio.

### BRIEF DESCRIPTION OF THE DRAWINGS

The structural features and effects of the present invention will be more clearly described, which will now be described in detail with reference to the accompanying drawings and specific embodiments.

FIG. 1 is a structure diagram of a liquid crystal display panel according to the present invention;

FIG. 2 is a top view diagram of a TFT array substrate shown in FIG. 1.

### DETAILED DESCRIPTION OF PREFERRED EMBODIMENTS

For better explaining the technical solution and the effect of the present invention, the present invention will be further described in detail with the accompanying drawings in the specific embodiments. The figures are for illustrative purposes only and are illustrative only but not to be construed as limiting the present application.

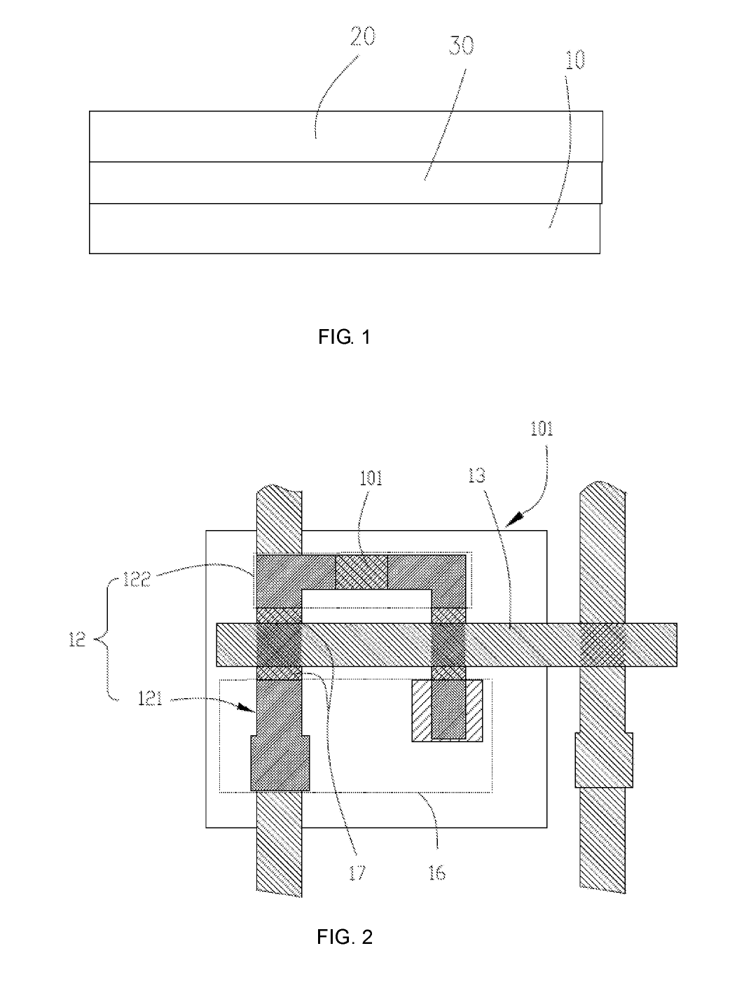

Please refer to FIG. 1 and FIG. 2. The present invention provides a TFT array substrate and a liquid crystal display panel, wherein the liquid crystal display panel comprises a color film substrate 20, a TFT array substrate 10 and a liquid crystal layer 30 between the color film substrate 20 and the TFT array substrate 10. The TFT array substrate comprises a plurality of pixels and a plurality of TFT switches corresponding to the pixels and being formed on the TFT substrate. The TFT switch 101 and a pixel region correspondingly provide electrical energy to the pixel.

Please refer to FIG. 2. In this embodiment, the TFT array substrate 10 comprises a substrate 11 and a plurality of TFT switches 101 formed on the substrate. One TFT switch is illustrated in this embodiment for explanation. The TFT switches 101 comprises a polysilicon layer 12, a gate 13, a first lightly doped region 14 and a heavy doped region 15. The polysilicon layer 12 and the gate 13 are spaced by an insulating layer. The polysilicon layer 12 comprises two opposite extending sections 121 and a main section 122 connecting ends of the two extending sections 121, and the gate 13 is disposed across the two extending sections 121, and the heavy doped region 15 is formed in the main section 122 of the polysilicon layer 12 and at one side of the gate 13, and the first lightly doped region 14 is formed at the middle of the heavily doped region 15.

In this embodiment, the polysilicon layer 12 appears to be an U-shaped structure. After the heavily doped region 15 is formed, the first lightly doped region 14 is formed by implementing second doping to the heavily doped region 15. When the TFT switch 101 is turned off, the resistance of the heavily doped region 15 becomes the key of controlling the leakage current. Because the first lightly doped region 14 is disposed on the heavily doped region 15 to increase the resistance of the TFT switch, and thus to reduce the leakage current. Meanwhile, in the manufacturing process, the length of the first lightly doped region 14 can be adjusted according to the pixel charging and discharging conditions of the TFT switch to meet the charging requirements under the premise of effectively reducing the leakage current.

The gate 13 is disposed across the two extending sections 121 and partially covers the extending sections 121. The overlapping region of the gate 13 and the extension sections 121 constitutes a channel region. The TFT switch 101 further comprises an auxiliary heavily doped region 16. The heavily doped region 15 and the auxiliary heavily doped region 16 are at two opposite sides of the gate 13, and both are spaced with the gate 13. The heavily doped region 15 is formed in the same process step as the auxiliary heavily doped region 16.

The TFT switch 101 further comprises second lightly doped regions 17, and the second lightly doped regions 17 are at a spaced position between the gate 13 and the heavily doped region 15, and at a spaced position between the gate 13 and the auxiliary heavily doped region 16. The first lightly doped region 14 is formed in the same process step as the second lightly doped region 17.

The TFT switch described in the present application provides a lightly doped region in the heavily doped region without affecting the aperture ratio of the array substrate and the manufacturing process, thereby effectively reducing the leakage current of the TFT switch and satisfying the TFT switching pixel charging requirement.

Above are only specific embodiments of the present invention, the scope of the present invention is not limited to this, and to any persons who are skilled in the art, change or replacement which is easily derived should be covered by the protected scope of the invention. Thus, the protected scope of the invention should go by the subject claims.

What is claimed is:

1. A TFT array substrate, comprising a substrate and a TFT switch formed on the substrate, wherein the TFT switch comprises a polysilicon layer, a gate, a first lightly doped region and a heavily doped region, and the polysilicon layer comprises two opposite extending sections and a main section connecting ends of the two extending sections, and the gate is disposed across the two extending sections, and the heavy doped region is formed in the main section of the polysilicon layer and at one side of the gate, and the first lightly doped region is formed at the middle of the heavily doped region.

2. The TFT array substrate according to claim 1, wherein an auxiliary heavily doped region is further disposed on the polysilicon layer at the other side of the gate.

3. The TFT array substrate according to claim 2, wherein the first lightly doped region is formed by implementing second doping to the heavily doped region.

4. The TFT array substrate according to claim 3, wherein the TFT switch comprises second lightly doped regions, and the second lightly doped regions are at two sides of the gate between the heavily doped region and the auxiliary heavily doped region.

5. The TFT array substrate according to claim 4, wherein the first lightly doped region is formed in the same process step as the second lightly doped region.

6. The TFT array substrate according to claim 1, wherein the gate and the polysilicon layer are formed on the substrate and spaced by an insulating layer.

7. A liquid crystal display panel, comprising a color film substrate, a TFT array substrate and a liquid crystal layer between the color film substrate and the TFT array substrate, wherein the TFT array substrate comprises a substrate and a TFT switch formed on the substrate, wherein the TFT switch comprises a polysilicon layer, a gate, a first lightly doped region and a heavily doped region, and the polysilicon layer comprises two opposite extending sections and a main section connecting ends of the two extending sections, and the gate is disposed across the two extending sections, and the heavy doped region is formed in the main section of the polysilicon layer and at one side of the gate, and the first lightly doped region is formed at the middle of the heavily doped region.

8. The liquid crystal display panel according to claim 7, wherein an auxiliary heavily doped region is further disposed on the polysilicon layer at the other side of the gate.

9. The liquid crystal display panel according to claim 8, wherein the first lightly doped region is formed by implementing second doping to the heavily doped region.

10. The liquid crystal display panel according to claim 8, wherein the TFT switch comprises second lightly doped regions, and the second lightly doped regions are at two sides of the gate between the heavily doped region and the auxiliary heavily doped region.

11. The liquid crystal display panel according to claim 10, wherein the first lightly doped region is formed in the same process step as the second lightly doped region.

12. The liquid crystal display panel according to claim 7, wherein the gate and the polysilicon layer are formed on the substrate and spaced by an insulating layer.
